(19) United States
(12) Patent Application Publication
(10) Pub. No.: US 2015/0382474 A1
(43) Pub. Date: Dec. 31, 2015

(54) METHOD FOR FABRICATING FLEXIBLE ELECTRONIC DEVICE AND SUBSTRATE FOR FABRICATING THE SAME

(71) Applicant: SHENZHEN ROYOLE TECHNOLOGY CO., LTD., Shenzhen (CN)

(72) Inventors: Zihong LIU, Shenzhen (CN); Xiaojun YU, Shenzhen (CN); Peng WEI, Shenzhen (CN)

(21) Appl. No.: 14/758,161

(22) PCT Filed: Dec. 28, 2012
(86) PCT No.: PCT/CN2012/087786

§ 371 Date: Jun. 26, 2015

(51) Int. Cl. H05K 3/02; H05K 3/30

(52) U.S. Cl. CPC H05K 3/02; H05K 3/30

(57) ABSTRACT

The present invention relates to the field of electronic device fabrication, provides a method for fabricating a flexible electronic device, and is intended to address the problems present in the prior art that the adhesive cannot be completely peeled off and the flexible substrate is damaged during peeling the flexible substrate from the rigid substrate in the flexible electronic device fabrication. The fabrication method comprises providing a channel on a rigid substrate; adhering a flexible substrate to the rigid substrate with an adhesive; fabricating an electronic device on the flexible substrate; injecting a chemical substance into the channel; and reacting the chemical substance with the adhesive, and peeling the flexible substrate from the rigid substrate. The present invention also provides a substrate for fabricating a flexible electronic device. In the present invention, a channel is provided on the rigid substrate to enhance the efficiency and speed of the reaction between the chemical substance with the adhesive, so that the flexible substrate can be completely and automatically peeled from the rigid substrate rapidly, and the chemical substance which reacts with the adhesive will not cause a damage to the flexible substrate or the electronic device.

### TECHNICAL FIELD

The invention belongs to the field of electronic device fabrication, particularly to a method for fabricating a flexible electronic device and a substrate for fabricating the same.

### BACKGROUND

Flexible electronic device is a new electronic technology that an electronic device of an organic/inorganic material is fabricated on a flexible/ductile plastic or a thin metal substrate, and due to the unique flexibility/ductility, and highly efficient and low-cost manufacturing process, it has found a broad application prospect in information, energy, medical, national defense and other fields, such as flexible electronic display, organic light emitting diode (OLED), printed RFID, thin-film solar panel, electronic surface patch (Skin Patches) and so on.

There are many problems present in the flexible substrate, such as fragile, easy-to-wrinkle, deformation, etc., which are particularly prominent in the actual fabrication process. The common method for fabricating a flexible electronic device is adhering a flexible substrate to a rigid substrate with a specific adhesive, then fabricating an electronic device on the side of the flexible substrate away from the rigid substrate, finally removing the adhesive by heating or laser melt-cutting method, thus peeling the flexible substrate from the rigid substrate to obtain a flexible electronic device, wherein the flexible electronic device is a flexible substrate provided with an electronic device. Although the two peeling methods have improved the peeling effects between the flexible substrate and the rigid substrate to some extent by the continuous improvement in the process conditions, the problems that the adhesive cannot be completely peeled off and the flexible substrate is damaged are still present, and the peeling process conditions are difficult to control, thus not facilitating the fabrication of a high-quality flexible electronic device.

### SUMMARY

An object of the present invention is to provide a method for fabricating a flexible electronic device and a substrate for fabricating the same, and is intended to address the problems present in the prior art that the adhesive cannot be completely peeled off and the flexible substrate is damaged during peeling the flexible substrates from the rigid substrate.

The embodiment of the present invention is carried out as follows, a method for fabricating a flexible electronic device, comprising the steps of:

providing a channel on a rigid substrate;

adhering a flexible substrate to the rigid substrate with an adhesive;

fabricating an electronic device on the flexible substrate;

injecting a chemical substance into the channel;

reacting the chemical substance with the adhesive, and peeling the flexible substrate from the rigid substrate.

Further, the adhesive is an adhesive polymer or film.

Further, the step of fabricating an electronic device on the flexible substrate comprises that at least one of the electronic devices and the wiring electrically connected to the electronic device are provided on the surface of the flexible substrate.

Further, the chemical substance is a chemical solvent or gas.

Further, the channel is a micro-channel, pattern, texture or groove provided on the first surface of the rigid substrate.

Further, the channel has at least one injection port, and the injection port is located on the side of the rigid substrate or the second surface opposite to the first surface.

Further, the channel is interconnected.

Further, the step of injecting the chemical substance into the channel comprises that the chemical substance is injected into the injection port of the rigid substrate; and the chemical substance flows into the channel along the injection port so as to contact and react with the adhesive.

Further, the channel is a via hole which is through the first surface of the rigid substrate and the second surface opposite to the first surface.

Further, the step of injecting the chemical substance into the channel comprises that the flexible substrate and the rigid substrate are immersed in a reaction vessel containing the chemical substance; and the chemical substance flows into the rigid substrate along the via hole so as to contact and react with the adhesive.

The present invention also provides a substrate for fabricating a flexible electronics device, comprising a flexible electronic device formed by the method for fabricating a flexible electronic device described above, a rigid substrate provided with a channel, and a adhesive applied to the rigid substrate and filled into the channel, wherein the adhesive adheres the flexible electronic device to the rigid substrate.

Further, the channel is a micro-channel, pattern, texture or groove provided on the first surface of the rigid substrate and interconnected, and the channel has at least one injection port located on the side of the rigid substrate; or the channel is a via hole which is through the rigid substrate.

In the present invention, a channel with an injection port or a via hole is provided on the rigid substrate to contact and react the chemical substance with the adhesive, so that the rigid substrate is completely and automatically peeled, and the used reaction conditions of the chemical substance and the adhesive will not cause a damage to the flexible substrate or the electronic device. By applying this method, it can be ensured that the flexible substrate will not occur the deformation or warpage phenomenon during fabricating the electronic device.

### BRIEF DESCRIPTION OF THE DRAWINGS

FIG. 1 is a flow chart of the method for fabricating a flexible electronic device according to the embodiment of the present invention.

FIG. 2 is a schematic plan view of the channel distribution of the rigid substrate according to the first embodiment of the present invention.

FIG. 3 is a schematic perspective view of the channel distribution of the rigid substrate according to the first embodiment of the present invention.

FIG. 4 is a schematic plan view of the channel distribution of the rigid substrate according to the second embodiment of the present invention.

FIG. 5 is a schematic cross-sectional view of the substrate for fabricating the flexible electronic device according to the first embodiment of the present invention.

FIG. 6 is a schematic cross-sectional view of the substrate for fabricating the flexible electronic device according to the second embodiment of the present invention.

FIG. 7 is a schematic cross-sectional view of the substrate for fabricating a flexible electronic device according to the second embodiment of the example of the present invention.

### DESCRIPTION OF EMBODIMENTS

In order to make the objects, technical solutions and advantages of the present invention more apparent, the present invention will be further described in detail in combination with the following accompanying drawings and examples. It should be understood that the particular embodiments described herein are merely to illustrate the present invention and are not intended to limit the same.

Referring to FIG. 1, the method for fabricating a flexible electronic device according to the present invention, comprises the steps of:

providing a channel 24 on a rigid substrate 20;

adhering a flexible substrate 40 to the rigid substrate 20 with an adhesive 60;

fabricating an electronic device 80 on the flexible substrate 40;

injecting a chemical substance 200 into the channel 24; and

reacting the chemical substance 200 with the adhesive 60, and peeling the flexible substrate 40 from the rigid substrate 20. In the above-described fabrication method, the channel 24 used to inject the chemical substance 200 is provided on the rigid substrate 20, to make the chemical substance 200 chemically react with the adhesive 60 adhered between the rigid substrate 20 and the flexible substrate 40 along the channel 24, so that the adhesive 60 is dissolved to peel the rigid substrate 20 from the flexible substrate 40. And, the chemical substance 200 chemically reacts with the adhesive 60 to completely remove the adhesive 60, so that the flexible substrate 20 is completely peel off, and at the same time, the flexible substrate 40 is no damaged, thus facilitating the fabrication of a high-quality flexible electronic device.

In the embodiment, the rigid substrate 20 is a quartz substrate or a glass substrate, but is not limited thereto. The rigid substrate 20 mainly provides a support effect for the subsequent fabrication process of the electronic device 80 so as to prevent the flexible substrate 20 from occurring the phenomena, such as breakages, winkles, deformations, etc.

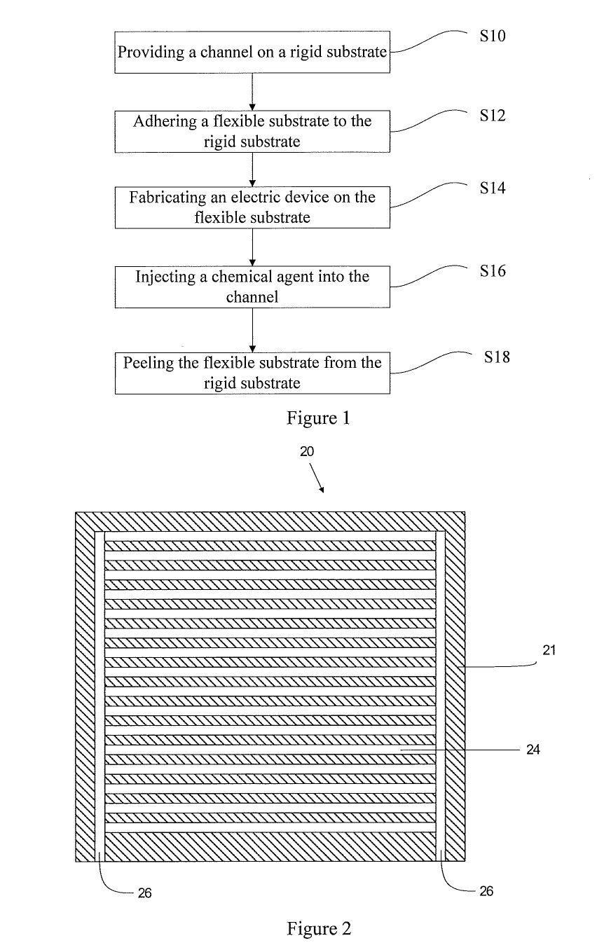

Also referring to FIGS. 2 to 4, the rigid substrate 20 comprises a first surface 21, a second surface 22 opposite to the first surface 21, and a side 23 located between the first surface 21 and the second surface 22. The first surface 21 faces toward the flexible substrate 40.

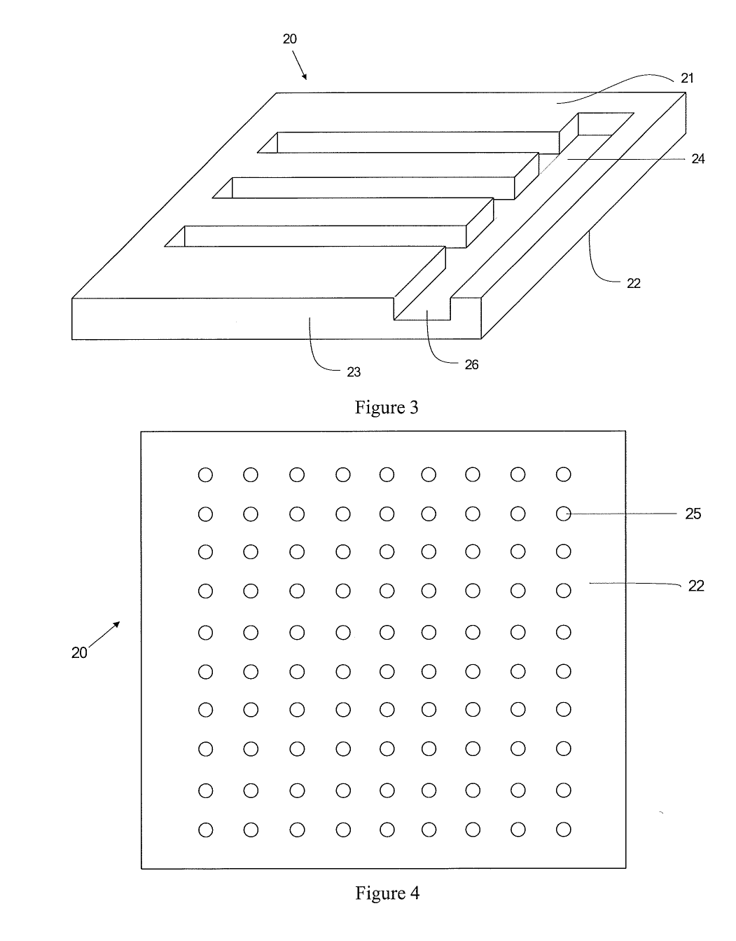

In a first embodiment of the present invention, the channel 24 is a micro-channel, pattern, texture or groove provided on the first surface 21 of the rigid substrate 20, as shown in FIGS. 2 and 3. The channel 24 can be in any shape, i.e. there is no limitation to the shape. The channel 24 is formed by etching or laser engraving. The channel 24 has at least one injection port 26, and the injection port is located on the side 23 of the rigid substrate 20, for example, an injection port 26 corresponding to a channel 24, so that the chemical substance 200 flows into the channel 24 along different injection port 26 to react with the adhesive 60. The injection port 26 may be in a square, circular or other shape, or formed by etching or laser engraving.

Further, the channel 24 is interconnected, particularly, the number of the injection port 26 may be one, i.e. the chemical substance 200 flows into the channel 24 along the injection port 26, or the number of the injection port 26 is two or the same as that of the channel 24, so that the chemical substance 200 can flow into the channel 24 along any one of injection ports 26, thus speeding up the reaction rate of the chemical substance 200 and the adhesive 60.

In another embodiment, the injection port 26 is provided on the second surface 22 and interconnected with the channel 24. The chemical substance 200 is injected via the injection port 26 and contacted with the adhesive 60.

In a second embodiment of the present invention, the channel 24 is a via hole 25 which is through the first surface 21 and the second surface 22, and the via hole 25 is formed through etching or laser engraving. In order to effectively contact and react the chemical substance 200 with the adhesive 60, there is provided with a plurality of via holes 25, and the number of the via holes 25 can be determined based on the size of the rigid substrate 20.

The adhesive 60 is applied to the first surface 21 of the rigid substrate 20, and the adhesive 60 is filled into the channel 24. The adhesive 60 can be an adhesive polymer or a film, and the adhesive polymer can be silica gel, rubber, epoxy or phenolic resin, and the like. When the adhesive 60 is applied, the dip coating method, roll coating method, die coating method, spray coating method, curtain coating method, spin coating method or dispensing method, and the like can be used. Dip coating method is carried out as follows: the first surface 21 of the rigid substrate 20 is immersed in a tank containing the adhesive 60 for a very short time, then the rigid substrate 20 is taken out from the tank and the excess adhesive 60 flows back into the tank. When the adhesive 60 is applied with a roll coating method, die coating method, spray coating method, curtain coating method or spin coating method, the adhesive 60 should be uniformly applied to the first surface 21. When the adhesive 60 is applied with the dispensing method, the adhesive 60 can form a plurality of adhesive patterns on the first surface 21, wherein the adhesive pattern should be uniformly distributed on the first surface 21.

The flexible substrate 40 is adhered to the rigid substrate 20 with the adhesive 60. Specifically, the flexible substrate 40 is covered on the adhesive 60, and the flexible substrate 40 is adhered to the rigid substrate 20 by curing the adhesive 60. In the embodiment, the manner for adhering the flexible substrate 40 to the rigid substrate 20 may be the common pressing or rolling, but is not limited thereto. The flexible substrate 40 can be a glass film substrate, stainless steel film substrate or plastic substrate, but is not limited thereto. The flexible substrate 40 has a thickness in a range of 5.5-550 micrometer.

In another embodiment, the adhesive 60 can also be firstly applied to the flexible substrate 40, and the flexible substrate 40 is adhered to the rigid substrate 20 by curing the adhesive 60.

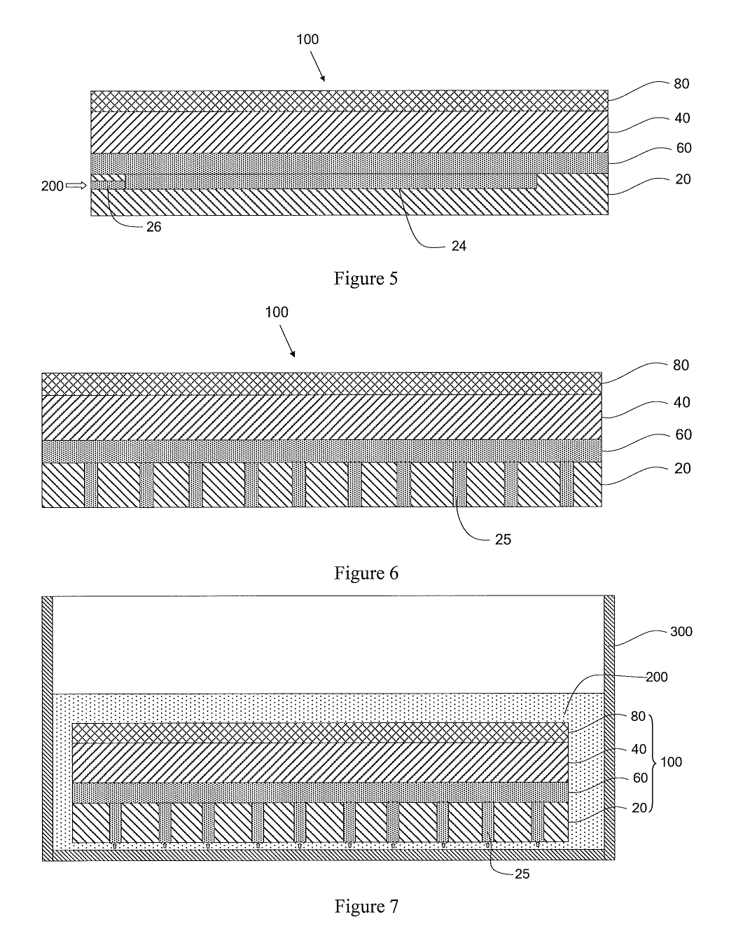

Referring to FIGS. 5 and 6, the electronic device 80 is fabricated on the flexible substrate 40. Due to the support effect of the rigid substrate 20, the fabrication of the electronic device 80 on the flexible substrate 40 adhered to the rigid substrate 20 can effectively prevent the flexible substrate 40 form occurring the phenomena, such as breakage, winkle and deformation during fabricating the electronic device 80. The fabrication of the electronic device 80 on the flexible substrate 20 comprises that at least one of the electronic devices 80 and the wiring electrically connected to the electronic device 80 are provided on the surface of the flexible substrate 20. The electronic device 80 can be a display element, a thin film transistor, a capacitor or a resistor, and the like, but is not limited thereto. During fabricating the electronic device 80, the longitudinal direction of the electronic device 80 should keep away from the bending direction of the flexible substrate 40, so as to prevent the damage to the electronic device 80 when the flexible substrate 40 is bent. For example, when the electronic device 80 is a display element, an organic light-emitting diode is fabricated and packaged on the flexible substrate 40. The method for packaging the light emitting diode comprises metal packaging method, glass packaging method, plastic packaging method or film packaging method, but is not limited thereto.

The chemical substance 200 can be a substance which can dissolve the adhesive 60, and can be a chemical solvent or gas. The chemical solvent is acetone, isopropanol or other dissolving agent. The gas can be a corrosive gas, such as fluorinated gas.

In one embodiment of the present invention, the step of injecting the chemical substance 20 into the channel 24 comprises that the chemical substance 20 is injected into the injection port 26 of the rigid substrate 20, and chemical substance 200 flows into the channel 24 along the injection port 26 so as to contact and react with the adhesive 60. Particularly, a chemical solvent, such as acetone or isopropanol, is injected into the injection port 26 of the rigid substrate 20, and the chemical substance flows into the channel 24 along the injection port 26 so as to contact and chemically react with the adhesive 60 such as rubber, epoxy or phenolic resin, so that the adhesive 60 is dissolved to peel the flexible substrate 40 from the rigid substrate 20, thus forming the flexible electronic device comprising the flexible substrate 40 and the electronic device 80.

In another embodiment of the present invention, the step of injecting the chemical substance 20 into the channel 24 comprises that the flexible substrate 40 and the rigid substrate 20 are immersed in a reaction vessel 300 containing the chemical substance 200, and the chemical substance 200 contacts and reacts with the adhesive 60 along the via hole 25. Particularly, in the reaction vessel 300 containing a chemical solvent such as acetone or isopropanol, acetone or isopropanol contacts and reacts with the adhesive 60, such as rubber, epoxy or a phenolic resin along the via hole 25, so that the adhesive 60 is dissolved to peel the flexible substrate 40 from the rigid substrate 20, thus forming the flexible electronic device comprising the flexible substrate 40 and the electronic devices 80, as shown in FIG. 7

In the embodiment, referring to FIG. 7, a fluorinated gas e.g., xenon fluoride, chlorine trifluoride, bromine trifluoride or fluorine gas is filled in the reaction vessel 300, and a silica gel adhesive 60 is dissolved. In reaction vessel 300 filled with xenon fluoride, the silica gel adhesive 60 carries out an isotropic chemical reaction with a fluorinated gas such as xenon fluoride, and the produced xenon gas and silicon tetrafluoride gas are escaped. When chlorine trifluoride, bromine trifluoride or fluorine gas is selected as the fluorinated gas, the reaction product of the silica gel adhesive 60 and the fluorinated gas is still an escaping gas, such as chlorine gas and silicon tetrafluoride gas, and as the silica gel adhesive 60 is completely reacted with the fluorinated gas, there are neither new additional foreign impurities, nor the residual silica gel adhesive 60 in the reaction process.

In summary, the chemical solvent or gas reacts with the adhesive 60 through the injection port 26 or via hole 25, so that the rigid substrate 20 is automatically and completely peeled off, thus effectively preventing the incomplete peeling phenomenon. And, the solubility of the acetone or isopropanol to the adhesive 60 and the reaction condition of the fluorinated gas and the silica gel adhesive 60 hardly cause a damage to the flexible substrates 40 and the electronic device 80, thus effectively avoiding the effect on the performances of the flexible substrate 40 and the electronic device 80 during peeling the rigid substrate 20, and, during peeling off the rigid substrate 20, the electronic device 80 and the circuit thereof will not be affected, thus facilitating the fabrication of a high-quality flexible electronic device.

In an embodiment of the present invention, a plurality of via holes 25 are designed to contact and react the chemical solvent or gas with the adhesive 60 in a large area range, so as to peel off the rigid substrate 20, thus accelerating the peeling speed, and also achieving the effect of effective peeling.

In order to accelerate the reaction between the chemical substance 200 with the adhesive 60, the size of the injection port 26 can be increased or the channel 24 is exposed on the side of the rigid substrate 20, so as to expose the adhesive 60, thus increasing the contact area between the chemical substance 200 and the adhesive 60, and accelerating the reaction.

The fabrication of the flexible electronic device is completed in combination with the abovementioned fabrication steps, also referring to FIGS. 5 and 6, the substrate 100 for fabricating the flexible electronic device comprises a flexible electronic device formed by the abovementioned method, a rigid substrate 20 provided with a channel 24, and an adhesive 60 applied to the rigid substrate 20 and filled into in the channel, wherein the adhesive 60 adheres the flexible electronic device to the rigid substrate 20. The flexible electronic device comprises the flexible substrate 20 and the electronic device 80 which is provided on the flexible substrate 40 and located on the side of the flexible substrate 40 away from the rigid substrate 20. In a first embodiment, the channel 24 is a micro-channel, pattern, texture or groove provided on the first surface 21 of the rigid substrate 20 and interconnected, and has at least one injection port 26 located on the side 23 of the rigid substrate 20. In a second embodiment, the rigid substrate 20 is provided with a plurality of via holes 25 which are through the rigid substrate 20, in particular, the via hole 25 is through the first surface 21 of the rigid substrate 20 and the second surface 22. After peeling off the rigid substrate 20, the flexible electronic device can be applied in the electronic device, thus improving the application range of the flexible electronic device, for example, it can be applied in flexible display, mobile phone, disk drive, CD walkman and the like.

In the present invention, the channel 24 with the injection port 26 or the via hole 25 is provided on the rigid substrate 20, to contact and react the chemical substance 200 with the adhesive 60, so that the rigid substrate 20 is completely and automatically peeled, and the used reaction conditions of the chemical substance 200 and the adhesive 60 will no cause a damage to the flexible substrate 40 or the electronic devices 80. By applying the method, it can be ensured that the flexible substrate 40 will not occur the phenomenon, such as deformation or warpage during fabricating the electronic device 80 so as to form a high-quality flexible electronic device, and effectively increase the rate for peeling the flexible substrate 40 from the rigid substrate 20, thus facilitating its application in production.

The method for fabricating a flexible electronic device according to the present invention is suitable to the case that a plurality of the flexible substrates 40 are integrated together to carry out a large area fabrication, after the fabrication of the electronic device 80 on the flexible substrate 40 is completed and before the rigid substrate 20 is peeled, a cutting step is carried out, which cannot only separate a plurality of the flexible substrates 40, but also expose the adhesive 60, so that the chemical substance 200 can rapidly react with the adhesive 60, thereby speeding up the rate of peeling the rigid substrate 20.

The foregoings are merely the preferred embodiments of the present invention, and are not intended to limit the present invention, any modification, equivalent replacement, improvement, etc., made within the spirit and principle of the present invention, should be encompassed in the scope of the present invention.

1. A method for fabricating a flexible electronic device, comprising the steps of:
providing a channel on a rigid substrate;
adhering a flexible substrate to the rigid substrate with an adhesive;
fabricating an electronic device on the flexible substrate;
injecting a chemical substance into the channel; and
reacting the chemical substance with the adhesive and peeling the flexible substrate from the rigid substrate.

2. A method for fabricating a flexible electronic device according to claim 1, wherein the step of fabricating an electronic device on the flexible substrate comprises:
at least one of the electronic devices and a wiring electrically connected to the electronic device are provided on the surface of the flexible substrate.

3. A method for fabricating a flexible electronic device according to claim 1, wherein the channel is a micro-channel, pattern, texture or groove provided on a first surface of the rigid substrate.

4. A method for fabricating a flexible electronic device according to claim 3, wherein the channel has at least one injection port, and the injection port is located on a side of the rigid substrate or a second surface opposite to the first surface.

5. A method for fabricating a flexible electronic device according to claim 4, wherein the channel is interconnected.

6. A method for fabricating a flexible electronic device according to claim 5, wherein the step of injecting the chemical substance into the channel comprises:
the chemical substance is injected into the injection port of the rigid substrate; and
the chemical substance flows into the channel along the injection port so as to contact and react with the adhesive.

7. A method for fabricating a flexible electronic device according to claim 1, wherein the channel is a via hole which is through the first surface of the rigid substrate and the second surface opposite to the first surface.

8. A method for fabricating a flexible electronic device according to claim 7, wherein the step of injecting the chemical substance into the channel comprises:
the flexible substrate and the rigid substrate are immersed in a reaction vessel containing the chemical substance; and
the chemical substance flows into the rigid substrate along the via hole so as to contact and react with the adhesive.

9. A substrate for fabricating a flexible electronic device, comprising a flexible electronic device formed by a method for fabricating a flexible electronic device according to claim 1, a rigid substrate provided with a channel, and an adhesive applied to the rigid substrate and filled into the channel, wherein the adhesive adheres the flexible electronic device to the rigid substrate.

10. A substrate for fabricating a flexible electronic device according to claim 9, wherein the channel is a micro-channel, pattern, texture or groove provided on the first surface of the rigid substrate and interconnected, and has at least one injection port located on a side of the rigid substrate; or the channel is a via hole which is through the rigid substrate.
